(19) United States
(12) Patent Application Publication
(10) Pub. No.: US 2025/0267835 A1
(43) Pub. Date: Aug. 21, 2025

(54) Device Including a Sense Amplifier and Method for Fabricating the Same

(71) Applicant: Taiwan Semiconductor Manufacturing Company, Ltd., Hsinchu (TW)

(72) Inventors: Jeehwan Song, Hsinchu (TW); Byoung Ju Kim, Hsinchu (TW); Radha Ramakrishnan, Hsinchu (TW); I Hui Tsai, Hsinchu (TW); Zhi Luo, Hsinchu (TW); Tianyi Liang, Hsinchu (TW)

(21) Appl. No.: 18/676,622

(22) Filed: May 29, 2024

Related U.S. Application Data
(60) Provisional application No. 63/555,451, filed on Feb. 20, 2024.

(51) Int. Cl. H10B 10/00; G06F 30/32; G11C 11/419

(52) U.S. Cl. CPC H10B 10/18; G06F 30/32; G11C 11/419

(57) ABSTRACT

A sense amplifier amplifies a voltage difference between complementary signal lines and includes first, second, third, and fourth components. The first component has a first gate region of a first transistor. The second component has a first gate region of a second transistor. The third component has a second gate region of the first transistor. The fourth component has a second gate region of the second transistor. Each of the first and second gate regions of the first and second transistors extends in a first direction. The first, second, third, and fourth components are arranged along a second direction transverse to the first direction. A method for fabricating a device including the sense amplifier is also disclosed.

### CROSS-REFERENCE TO RELATED APPLICATION

The present application claims priority to U.S. Provisional Application No. 63/555,451, filed Feb. 20, 2024, the contents of which are incorporated by reference herein in its entirety.

### BACKGROUND

A sense amplifier of a memory device detects a voltage difference between complementary signal lines, e.g., complementary bit or data lines, representing a bit (e.g., logic state ‘0’ or ‘1’) stored in a memory cell of the memory device. A sense amplifier may also be configured to amplify the voltage difference detected thereby to a level that can be accurately interpreted or read, such as by a memory controller of the memory device.

### BRIEF DESCRIPTION OF THE DRAWINGS

Aspects of the present disclosure are best understood from the following detailed description when read with the accompanying figures:

FIG. 1 is a schematic block diagram illustrating an exemplary device in accordance with various embodiments of the present disclosure;

FIG. 2 is a schematic circuit diagram illustrating an exemplary sense amplifier of a device in accordance with various embodiments of the present disclosure;

FIG. 3 is a schematic layout diagram illustrating an exemplary sense amplifier layout of a device in accordance with various embodiments of the present disclosure;

FIG. 4 is a schematic layout diagram illustrating another exemplary sense amplifier layout of a device in accordance with various embodiments of the present disclosure;

FIG. 5 is a schematic layout diagram illustrating another exemplary sense amplifier layout of a device in accordance with various embodiments of the present disclosure;

FIG. 6 is a schematic layout diagram illustrating another exemplary sense amplifier layout of a device in accordance with various embodiments of the present disclosure;

FIG. 7 is a schematic layout diagram illustrating another exemplary sense amplifier layout of a device in accordance with various embodiments of the present disclosure;

FIG. 8 is a schematic layout diagram illustrating another exemplary sense amplifier layout of a device in accordance with various embodiments of the present disclosure;

FIG. 9 is a flow chart illustrating an exemplary method of designing a layout of a sense amplifier of a device in accordance with various embodiments of the present disclosure;

FIG. 10 is a flow chart illustrating another exemplary method of designing a layout of a sense amplifier of a device in accordance with various embodiments of the present disclosure;

FIG. 11 is a flow chart illustrating another exemplary method of designing a layout of a sense amplifier of a device in accordance with various embodiments of the present disclosure; and

FIG. 12 is a flow chart illustrating an exemplary method of manufacturing a device using a sense amplifier layout in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underneath,” “below,” “lower,” “above,” “on,” “top,” “bottom” and the like, may be used herein for ease of description to describe one element or feature's relationship to another element(s) or feature(s) as illustrated in the figures. The spatially relative terms are intended to encompass different orientations of the structure in use or operation in addition to the orientation depicted in the figures. The apparatus may be otherwise oriented (rotated 90 degrees or at other orientations) and the spatially relative descriptors used herein may likewise be interpreted accordingly.

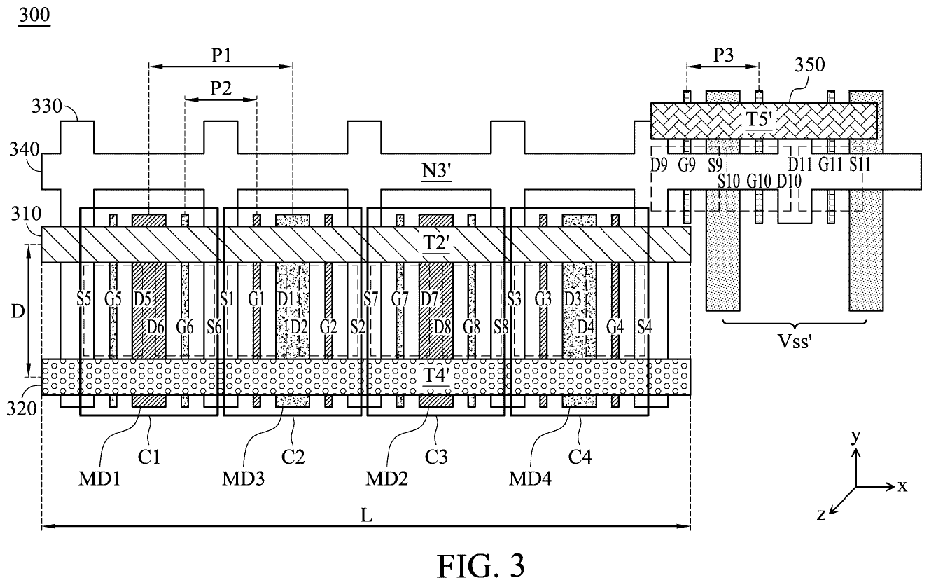

Memory devices, e.g., a static random access memory (SRAM) device, may be designed to include sense amplifiers to assist with certain operations. For example, during a read operation of a memory device, a sense amplifier may be configured to detect a voltage difference between complementary signal lines, e.g., complementary bit or data lines, representing a bit (e.g., logic state ‘0’ or ‘1’) of data stored in a memory cell of the memory device. The sense amplifier may be further configured to amplify the voltage difference detected thereby to a level that can be accurately interpreted and read by a memory controller of the memory device. In some instances, even before a read operation, a voltage difference, also known as an offset voltage, may exist between the complementary signal lines. Such an offset voltage, e.g., those caused by imbalances between the resistance (and/or the capacitance) of the signal line and the resistance (and/or the capacitance) of the complement signal line, can slow read operations on the memory device. Certain systems and methods as described herein can mitigate issues caused by offset voltages by, e.g., swapping components, such as components (C1-C4) in FIG. 3, of a sense amplifier.

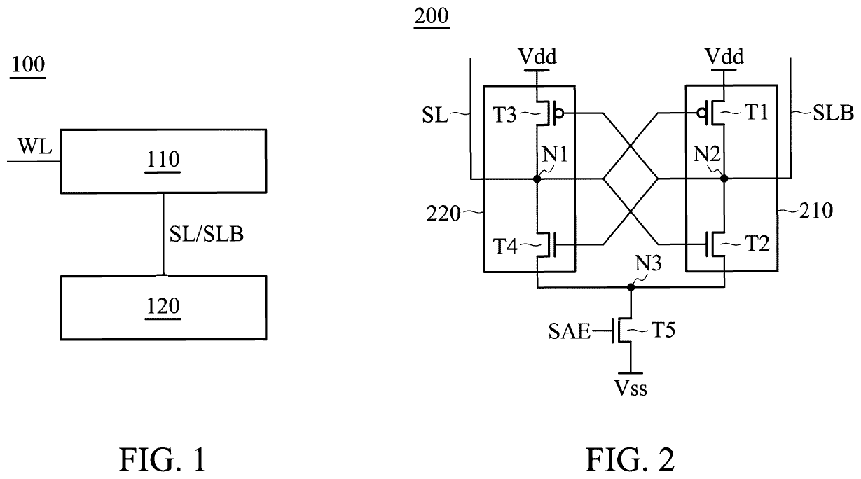

In certain examples described herein, systems and methods comprise a sense amplifier (e.g., sense amplifier 200 of FIG. 2) layout (e.g. layout 300 of FIG. 3) that includes a plurality of components (C1-C4). Each component (C1-C4) has a source region, a drain region, and a gate region between the source and drain regions. The components (C1-C4) are arranged in an order such that the sense amplifier 200 has an offset voltage of approximately 0V, e.g., less than 1 mV. In further detail, FIG. 1 is a schematic block diagram illustrating an exemplary device 100 in accordance with various embodiments of the present disclosure.

As illustrated in FIG. 1, the example device 100, e.g., a memory device, such as an SRAM device, includes a memory circuit 110, a plurality of word lines (WL), a complementary signal lines (SL, SLB), and a sensing circuit 120. The memory circuit 110 includes a plurality of memory cells and a memory controller. The memory cells are arranged in an array of rows and columns and each store a bit, e.g., logic state ‘0’ or ‘1’, of data.

The word line (WL) extends horizontally and is connected between the memory controller and the memory cells in a row. The complementary signal lines (SL, SLB), e.g., complementary bit or data lines, each extend vertically and are connected between the memory controller and the memory cells in a column.

The sensing circuit 120 includes a sense amplifier, e.g., sense amplifier 200 in FIG. 2, connected between the complementary signal lines (SL, SLB), detects a voltage difference therebetween, and amplifies the voltage difference detected thereby. The memory controller reads bits of data from the memory cells based on the voltage differences amplified by the sense amplifier 200. As will described in detail further below, the order of components, e.g., components (C1-C4) in FIG. 3, of the sense amplifier 200 and/or the lengths of metal lines, e.g., metal lines 310, 320 in FIG. 3, facilitate balancing the resistance (and/or the capacitance) of the signal line (SL) and the resistance (and/or the capacitance) of the complement signal line (SLB). This optimizes the offset voltage of the sense amplifier 200 to approximately 0V, e.g., less than 1 mV, whereby the bit stored in the memory cell can be accurately read by the memory controller in a relatively shorter time.

Example supporting circuitry for a sense amplifier 200 of the device 100 is depicted in FIG. 2. It is understood that this circuitry is provided by way of example, not by limitation, and other suitable sense amplifier 200 circuitry are within the scope of the present disclosure. FIG. 2 is a schematic circuit diagram illustrating an exemplary sense amplifier 200 of the device 100 in accordance with various embodiments of the present disclosure. As illustrated in FIG. 2, the sense amplifier 200 includes sense amplifier 200 nodes (N1-N3), cross-coupled inverters 210, 220, and a transistor (T5). The sense amplifier 200 node (N1) serves as the input of the inverter 210 and the output of the inverter 220 and is connected to the signal line (SL).

The sense amplifier 200 node (N2) serves as the input of the inverter 220 and the output of the inverter 210 and is connected to the complement signal line (SLB). Each inverter 210, 220 includes a p-type metal-oxide-semiconductor (PMOS) transistor (T1, T3) and an n-type metal-oxide-semiconductor (NMOS) transistor (T2, T4). The PMOS transistor (T1) has a source terminal connected to a supply voltage (Vdd) node that receives a supply voltage (Vdd), a drain terminal connected to the sense amplifier 200 node (N2), and a gate terminal connected to the sense amplifier 200 node (N1). The NMOS transistor (T2) has a drain terminal connected to the sense amplifier 200 node (N2), a source terminal connected to the sense amplifier 200 node (N3), and a gate terminal connected to the sense amplifier 200 node (N1).

The PMOS transistor (T3) has a source terminal connected to the supply voltage (Vdd) node, a drain terminal connected to the sense amplifier 200 node (N1), and a gate terminal connected to the sense amplifier 200 node (N2). The NMOS transistor (T4) has a drain terminal connected to the sense amplifier 200 node (N1), a source terminal connected to the sense amplifier 200 node (N3), and a gate terminal connected to the sense amplifier 200 node (N2).

The NMOS transistor (T5) has a drain terminal connected to the sense amplifier 200 node (N3), a source terminal connected to a Vss (or ground) node and a gate terminal that receives a sense amplifier 200 enable (SAE) signal. In this exemplary embodiment, the transistor (T5) includes an NMOS transistor. In an alternative embodiment, the transistor (T5) includes one or more NMOS transistors. In an exemplary read operation, the complementary signal lines (SL, SLB) are initially pre-charged to a reference voltage level, e.g., the supply voltage (Vdd). When a SAE signal is asserted, the transistor (T5) turns on, activating the sense amplifier 200. At this time, one of the inverters 210, 220 amplifies the voltage on one of the complementary signal lines (SL, SLB), consequently driving its output to a logic state (e.g., ‘1’ or ‘0’). Simultaneously, the input of the other of the inverters 210, 220 is pulled toward the opposite logic state, thereby stabilizing the logic state at the signal line (SL), whereby a memory controller accurately reads a bit stored in a memory cell. Thereafter, the sense amplifier 200 is deactivated and the complementary signal lines (SL, SLB) may be pre-charged again in preparation for the next read operation.

FIG. 3 is a schematic layout diagram illustrating an exemplary sense amplifier 200 layout 300 of the device 100 in accordance with various embodiments of the present disclosure. As illustrated in FIG. 3, the example sense amplifier 200 layout 300 includes a transistor (T2) layout portion (T2′), a transistor (T4) layout portion (T4′), a sense amplifier 200 node (N3) layout portion (N3′), a transistor (T5) layout portion (T5′), and a Vss (or ground) node layout portion (Vss′). The transistor (T2) layout portion (T2′) includes a plurality of fingers (G1-G4), a metal line 310, a plurality of metal-diffusion (MD) layers (MD1, MD2), a plurality of source regions (S1-S4), and a plurality of drain regions (D1-D4).

The fingers (G1-G4) each extend in a first direction (y), are arranged along a second direction (x) transverse to the first direction (y), and serve as gate regions of the transistor (T2). Although the transistor (T2) layout portion (T2′) is exemplified with only four fingers or gate regions (G1-G4), it should be apparent that, after reading this disclosure, the number of fingers or gate regions of the transistor (T2) layout portion (T2′) may be increased or decreased as desired.

The metal line 310 is connected to the signal line (SL), extends in the second direction (x), and interconnects the gate regions (G1-G4). The MD layers (MD1, MD2) each extend in the first direction (y) and are arranged along the length of the metal line 310. Each source region (S1-S4) is disposed at one side of the respective gate region (G1-G4), whereas each drain region (D1-D4) is disposed at the opposite side of the respective gate region (G1-G4).

In this exemplary embodiment, the transistor (T4) layout portion (T4′) has substantially the same shape as the transistor (T2) layout portion (T2′). For example, the transistor (T4) layout portion (T4′) includes a plurality of fingers (G5-G8), a metal line 320, a plurality of MD layers (MD3, MD4), a plurality of source regions (S5-S8), and a plurality of drain regions (D5-D8). The fingers (G5-G8) each extend in the first direction (y), are arranged along the second direction (x), serve as gate regions of the transistor (T4), and overlap the metal line 310 in a third direction (z) transverse to the first and second directions (y, x). Although the transistor (T4) layout portion (T4′) is exemplified with only four fingers or gate regions (G5-G8), it should be apparent that, after reading this disclosure, the number of fingers or gate regions of the transistor (T4) layout portion (T4′) may be increased or decreased as desired.

The metal line 320 is connected to the complement signal line (SLB), extends in the second direction (x), is spaced-apart from the metal line 310 in the first direction (y), interconnects the gate regions (G5-G8), and overlaps the gate regions (G1-G4) and the MD layers (MD1, MD2) in the third direction (z). In this exemplary embodiment, the metal lines 310, 320 have substantially the same length and width. The MD layers (MD3, MD4) each extend in the first direction (y), are arranged along the length of the metal line 320, and overlap the metal line 310 in the third direction (z). Each source region (S5-S8) is disposed at one side of the respective gate region (G5-G8), whereas each drain region (D5-D8) is disposed at the opposite side of the respective gate region (G5-G8).

In addition, as illustrated in FIG. 3, the MD layers (MD1-MD4) have a pitch (P1). The gate regions (G1-G8) have a pitch (P2) less than the pitch (P1). In this exemplary embodiment, the metal lines 310, 320 define a distance (D) therebetween greater than the pitch (P1). In an alternative embodiment, the distance (D) is substantially equal to or less than the pitch (P1). In some embodiments, the distance (D) is less than the pitch (P2). In other embodiments, the distance (D) is substantially equal to or greater than the pitch (P2).

Moreover, as illustrated in FIG. 3, the sense amplifier 200 layout 300 is divided into a plurality of components (C1-C4). The component (C1) includes the MD layer (MD1), the gate regions (G5, G6), the source regions (S5, S6), and the drain regions (D5, D6). The component (C2) includes the MD layer (MD3), the gate regions (G1, G2), the source regions (S1, S2), and the drain regions (D1, D2). The component (C3) includes the MD layer (MD2), the gate regions (G7, G8), the source regions (S7, S8), and the drain regions (D7, D8). The component (C4) includes the MD layer (MD4), the gate regions (G3, G4), the source regions (S3, S4), and the drain regions (D3, D4).

Further, as illustrated in FIG. 3, when viewed from top to bottom, the metal lines 310, 320 are above the gate regions (G1-G8) and the MD layers (MD1-MD4). Also, when viewed from top to bottom, the metal lines 340, 350 are above the gate regions (G9, G11).

In this exemplary embodiment, the components (C1-C4) are arranged along the second direction (x) from left to right. For example, the components (C2, C3) are interposed between the components (C1 and C4). The component (C2) is interposed between the components (C1, C3). The component (C3) is interposed between the components (C2, C4).

The sense amplifier 200 node (N3) layout portion (N3′) has a first portion that overlaps the transistor (T2, T4) layout portion (T2′, T4′) in the third direction (z) and includes a plurality of first metal lines 330 and a second metal line 340. The first metal lines 330 each extend in the first direction (y) and are arranged along the second direction (x). The second metal line 340 extends in the second direction (x) and interconnects the first metal lines 330.

The transistor (T5) layout portion (T5′) overlaps a second portion of the sense amplifier 200 node (N3) layout portion (N3′) in the third direction (z) and includes a plurality of fingers (G9-G11), a metal line 350, a plurality of source regions (S9-S11), and a plurality of drain regions (D9-D11). The fingers (G9-G11) each extend in the first direction (y), are arranged along the second direction (x), and serve as gate regions of the transistor (T5). In this exemplary embodiment, the fingers of gate regions (G9-G11) have a pitch (P3) substantially equal to the pitch (P2).

Although the transistor (T5) layout portion (T5′) is exemplified with only three fingers or gate regions (G9-G11), it should be apparent that, after reading this disclosure, the number of fingers or gate regions of the transistor (T5) layout portion (T5′) may be increased or decreased as desired.

The metal line 350 extends in the second direction (x), interconnects the gate regions (G9-G11), and receives the SAE signal. Each source region (S9-S11) is disposed at one side of the respective gate region (G9-G11), whereas each drain region (D9-D11) is disposed at the opposite side of the respective gate region (G9-G11). The Vss (or ground) node layout portion (Vss′) overlaps the second portion of the sense amplifier 200 node (N3) layout portion (N3′) in the third direction (z) and includes one or more metal lines that each extend in the first direction (y) and that are arranged along the second direction (x).

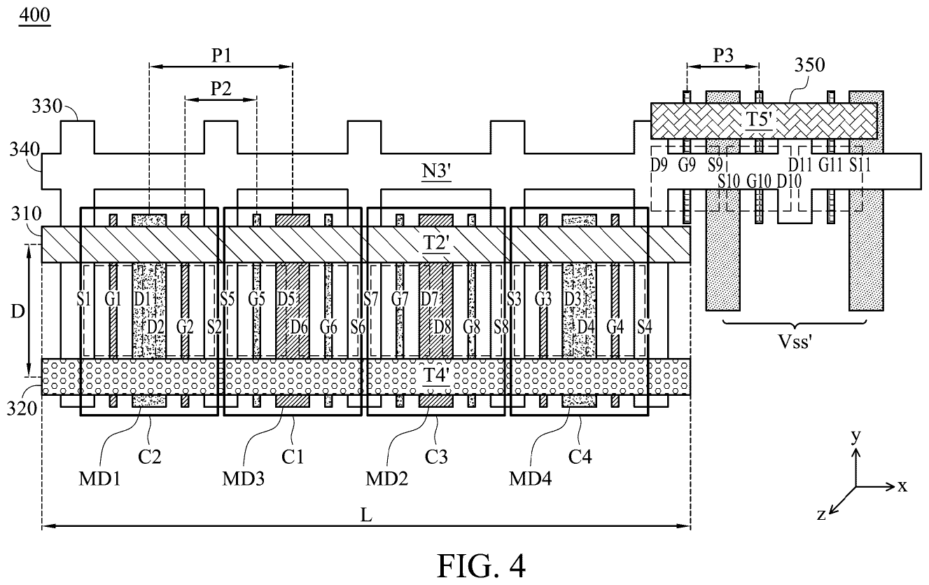

Although the sense amplifier 200 layout 300 is exemplified such that the components (C1-C4) are arranged along the second direction (x) from left to right, it should be understood that, after reading this disclosure, the order of the components (C1-C4) may be altered to optimize the offset voltage of the sense amplifier 200. For example, rather than from left to right, the components (C1-C4) may be arranged along the second direction (x) from right to left. Such a modification may result in a smaller offset voltage for the sense amplifier 200 of substantially 0V, e.g., less than 1 mV. For example, FIGS. 4-6 are schematic layout diagrams illustrating another exemplary sense amplifier 200 layouts 400-600 of the device 100 in accordance with various embodiments of the present disclosure.

As illustrated in FIG. 4, the example sense amplifier 200 layout 400 differs from the example sense amplifier 200 layout 300 in that the components (C1, C3) are interposed between the components (C2, C4). The component (C1) is interposed between the components (C2, C3). The component (C3) is interposed between the components (C1, C4). In addition, the gate region (G1, G2) of the transistor (T2) layout portion (T2′) and the gate region (G5, G6) of the transistor (T4) layout portion (T4′) are respectively distal from and proximate to the transistor (T5) layout portion (T5′).

The transistor (T2) layout portion (T2′) and the transistor (T4) layout portion (T4′) of the sense amplifier 200 layout 400 have different shapes from each other. That is, the shapes of the transistor (T2) layout portion (T2′) and the transistor (T4) layout portion (T4′) of the sense amplifier 200 layout 400, unlike in the sense amplifier 200 layout 300, do not have to be identical. The construction as such of the sense amplifier 200 layout 400 may provide a better balance between the resistance (and/or the capacitance) of the signal line (SL) and the resistance (and/or capacitance) of the complement signal line (SLB), resulting in a smaller offset voltage than the sense amplifier 200 layout 300.

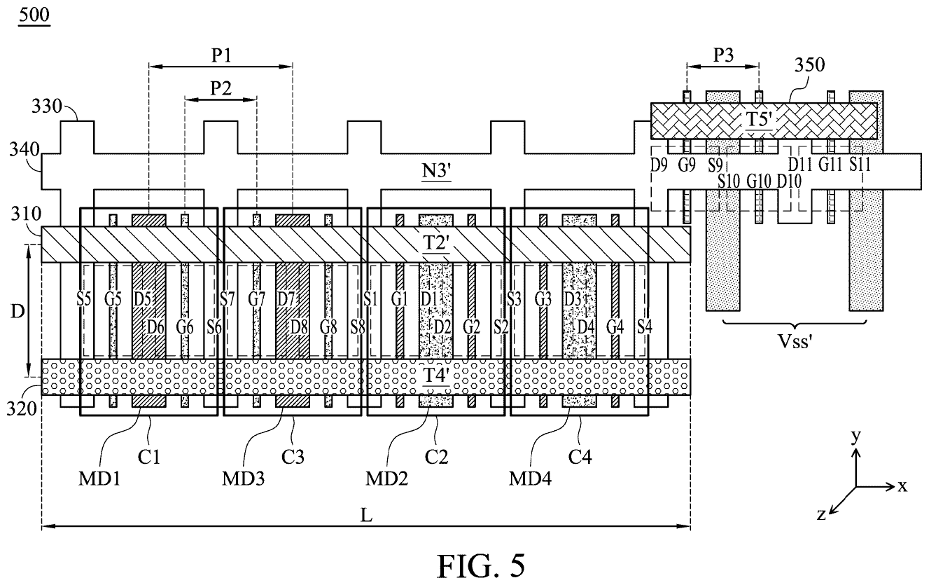

As illustrated in FIG. 5, the example sense amplifier 200 layout 500 differs from the example sense amplifier 200 layout 300 in that the component (C3) is interposed between the components (C1, C2). The component (C2) is interposed between the components (C3, C4). In addition, the gate region (G1, G2) of the transistor (T2) layout portion (T2′) and the gate region (G7, G8) of the transistor (T4) layout portion (T4′) are respectively proximate to and distal from the transistor (T5) layout portion (T5′).

The transistor (T2) layout portion (T2′) and the transistor (T4) layout portion (T4′) of the sense amplifier 200 layout 500 have different shapes from each other. That is, the shapes of the transistor (T2) layout portion (T2′) and the transistor (T4) layout portion (T4′) of the sense amplifier 200 layout 500, unlike in the sense amplifier 200 layout 300, do not have to be identical. The construction as such of the sense amplifier 200 layout 500 may provide a better balance between the resistance (and/or the capacitance) of the signal line (SL) and the resistance (and/or capacitance) of the complement signal line (SLB), resulting in a smaller offset voltage than the sense amplifier 200 layout 300.

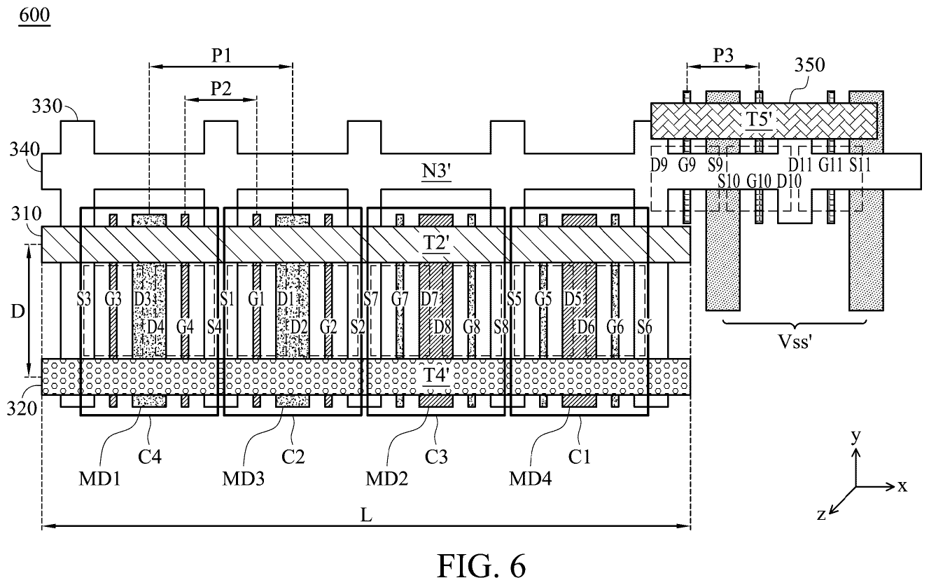

As illustrated in FIG. 6, the example sense amplifier 200 layout 600 differs from the example sense amplifier 200 layout 300 in that the component (C2) is interposed between the components (C3, C4). The component (C3) is interposed between the components (C1, C2). In addition, the gate region (G3, G4) of the transistor (T2) layout portion (T2′) and the gate region (G5, G6) of the transistor (T4) layout portion (T4′) are respectively distal from and proximate to the transistor (T5) layout portion (T5′).

The transistor (T2) layout portion (T2′) and the transistor (T4) layout portion (T4′) of the sense amplifier 200 layout 600 have different shapes from each other. That is, the shapes of the transistor (T2) layout portion (T2′) and the transistor (T4) layout portion (T4′) of the sense amplifier 200 layout 600, unlike in the sense amplifier 200 layout 300, do not have to be identical. The construction as such of the sense amplifier 200 layout 600 may provide a better balance between the resistance (and/or the capacitance) of the signal line (SL) and the resistance (and/or capacitance) of the complement signal line (SLB), resulting in a smaller offset voltage than the sense amplifier 200 layout 300.

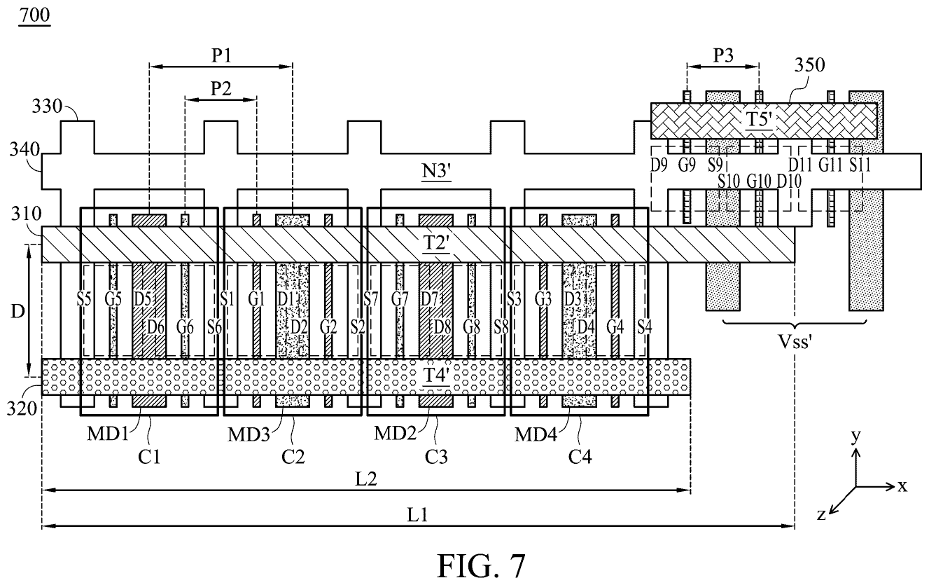

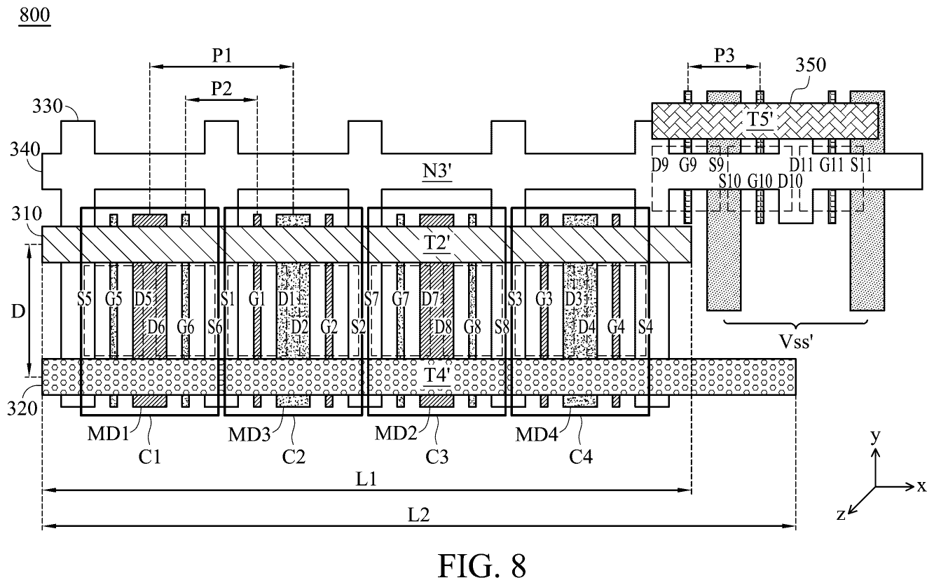

Furthermore, although the sense amplifier 200 layout 300 is exemplified such that the metal lines 310, 320 have substantially the same length (L), it should be understood that, after reading this disclosure, the lengths of the metal lines 310, 320 may be altered to optimize the offset voltage of the sense amplifier 200. For example, FIGS. 7 and 8 are schematic layout diagrams illustrating another exemplary sense amplifier 200 layouts 700, 800 of the device 100 in accordance with various embodiments of the present disclosure.

As illustrated in FIG. 7, the example sense amplifier 200 layout 700 differs from the example sense amplifier 200 layout 300 in that the metal line 310 has a length (L1) greater than a length (L2) of the metal line 320. The transistor (T2) layout portion (T2′) and the transistor (T4) layout portion (T4′) of the sense amplifier 200 layout 700 have different shapes from each other. That is, the shapes of the transistor (T2) layout portion (T2′) and the transistor (T4) layout portion (T4′) of the sense amplifier 200 layout 700, unlike in the sense amplifier 200 layout 300, do not have to be identical. The construction as such of the sense amplifier 200 layout 700 may provide a better balance between the resistance (and/or the capacitance) of the signal line (SL) and the resistance (and/or capacitance) of the complement signal line (SLB), resulting in a smaller offset voltage than the sense amplifier 200 layout 300.

As illustrated in FIG. 8, the example sense amplifier 200 layout 800 differs from the example sense amplifier 200 layout 300 in that the metal line 320 has a length (L2) greater than a length (L1) of the metal line 310. The transistor (T2) layout portion (T2′) and the transistor (T4) layout portion (T4′) of the sense amplifier 200 layout 800 have different shapes from each other. That is, the shapes of the transistor (T2) layout portion (T2′) and the transistor (T4) layout portion (T4′) of the sense amplifier 200 layout 800, unlike in the sense amplifier 200 layout 300, do not have to be identical. The construction as such of the sense amplifier 200 layout 800 may provide a better balance between the resistance (and/or the capacitance) of the signal line (SL) and the resistance (and/or capacitance) of the complement signal line (SLB), resulting in a smaller offset voltage than the sense amplifier 200 layout 300.

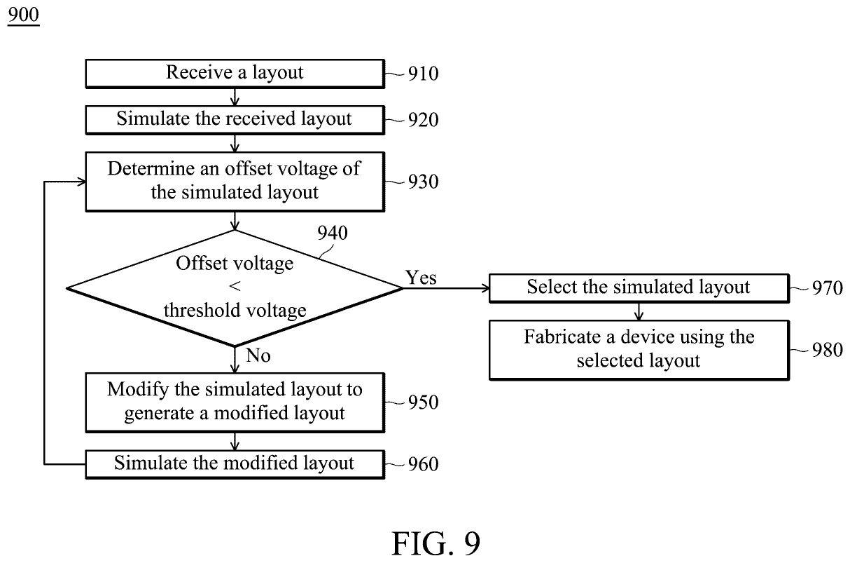

FIG. 9 is a flow chart of an exemplary method 900 for designing a layout of the sense amplifier 200 of the device 100 in accordance with various embodiments of the present disclosure. The example method 900 will now be described with further reference to FIGS. 2-8 for ease of understanding. It is understood that the method 900 is applicable to structures other than those of FIGS. 2-8. Further, it is understood that additional operations can be provided before, during, and after the method 900, and some of the operations described below can be replaced or eliminated, in an alternative embodiment of the method 900.

In operation 910, the layout design tool, such as an electronic design automation (EDA) tool, receives a layout of a sense amplifier 200 of a device 100, e.g., one of the sense amplifier 200 layouts 300-800. In operation 920, the layout design tool simulates the layout received in operation 910. In operation 930, the layout design tool determines an offset voltage of the layout simulated in operation 920 or operation 960. In operation 940, when it is determined that the offset voltage is less than a threshold voltage, i.e., substantially 0V, e.g., 1 mV, the flow proceeds to operation 970. Otherwise, i.e., the offset voltage is equal to or greater than the threshold voltage, the flow proceeds to operation 950.

In operation 950, the layout engineer (or the layout design tool) modifies the layout simulated in operation 920 or operation 960 to generate a modified layout. For example, the layout engineer (or the layout design tool) alters the order of the components (C1-C4) and/or adjusts the length of the metal line 310 and/or the length of the metal line 320, thereby balancing the resistance (and/or the capacitance) of the signal line (SL) and the resistance (and/or the capacitance) of the complement signal line (SLB). In operation 960, the layout design tool simulates the modified layout. Thereafter, the flow goes back to operation 930. In operation 970, the layout engineer (or the layout design tool) selects the layout simulated in operation 920 or operation 960. In operation 980, the device manufacturing tool fabricates the device 100 using the layout selected in operation 970.

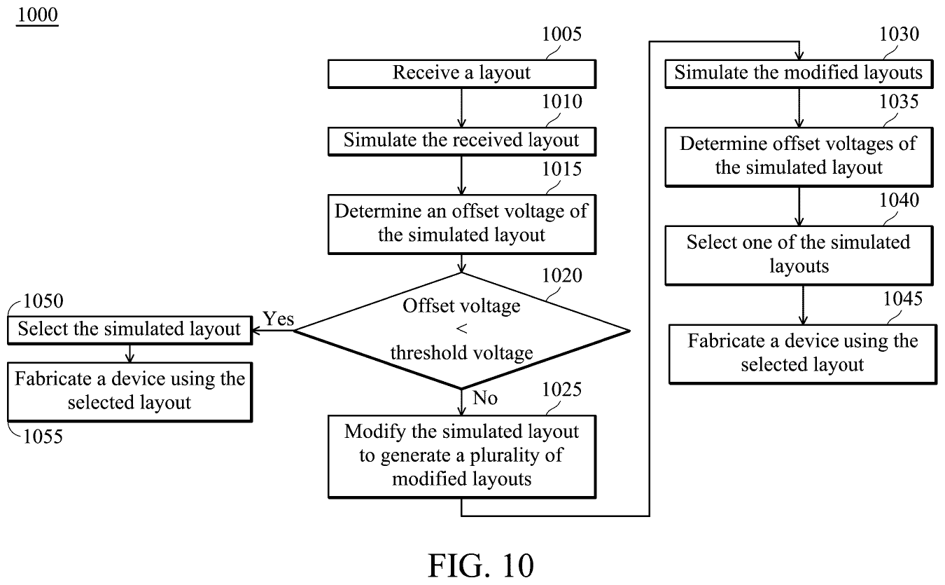

FIG. 10 is a flow chart of another exemplary method 1000 for designing a layout of the sense amplifier 200 of the device 100 in accordance with various embodiments of the present disclosure. The example method 1000 will now be described with further reference to FIGS. 2-8 for ease of understanding. It is understood that the method 1000 is applicable to structures other than those of FIGS. 2-8. Further, it is understood that additional operations can be provided before, during, and after the method 1000, and some of the operations described below can be replaced or eliminated, in an alternative embodiment of the method 1000.

In operation 1005, the layout design tool, such as an EDA tool, receives a layout of a sense amplifier 200 of a device 100, e.g., one of the sense amplifier 200 layouts 300-800. In operation 1010, the layout design tool simulates the layout received in operation 1005. In operation 1015, the layout design tool determines an offset voltage of the layout simulated in operation 1010. In operation 1020, when it is determined that the offset voltage is less than a threshold voltage, i.e., substantially 0V, e.g., 1 mV, the flow proceeds to operation 1050. Otherwise, i.e., the offset voltage is equal to or greater than the threshold voltage, the flow proceeds to operation 1025.

In operation 1025, the layout engineer (or the layout design tool) modifies the layout simulated in operation 1010 to generate a plurality of modified layouts. For example, the layout engineer (or the layout design tool) alters the order of the components (C1-C4) and/or adjusts the length of the metal line 310 and/or the length of the metal line 320, thereby balancing the resistance (and/or the capacitance) of the signal line (SL) and the resistance (and/or the capacitance) of the complement signal line (SLB). In operation 1030, the layout design tool simulates the modified layouts.

In operation 1035, the layout design tool determines the offset voltages of the layouts simulated in operation 1030. In operation 1040, the layout engineer (or the layout design tool) selects one of the layouts simulated in operation 1030, e.g., the layout having an offset voltage nearest to 0V. In operation 1045, the device manufacturing tool fabricates the device 100 using the layout selected in operation 1040. In operation 1050, the layout engineer (or the layout design tool) selects the layout simulated in operation 1010. In operation 1055, the device manufacturing tool fabricates the device 100 using the layout selected in operation 1050.

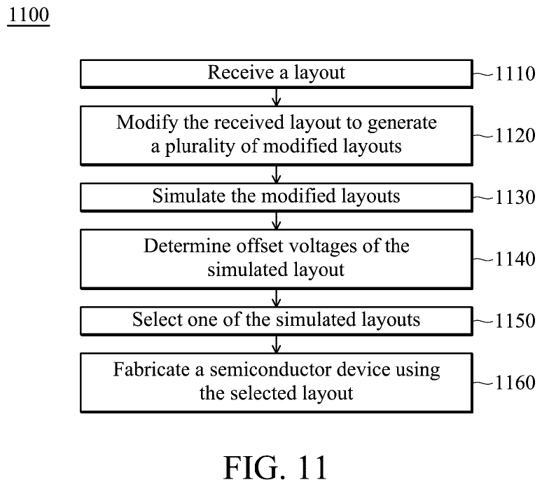

FIG. 11 is a flow chart of another exemplary method 1100 for designing a layout of the sense amplifier 200 of the device 100 in accordance with various embodiments of the present disclosure. The example method 1100 will now be described with further reference to FIGS. 2-8 for ease of understanding. It is understood that the method 1100 is applicable to structures other than those of FIGS. 2-8. Further, it is understood that additional operations can be provided before, during, and after the method 1100, and some of the operations described below can be replaced or eliminated, in an alternative embodiment of the method 1100.

In operation 1110, the layout design tool, such as an EDA tool, receives a plurality of layouts of a sense amplifier 200 of a device 100, e.g., the sense amplifier 200 layouts 300-800. In operation 1120, the layout engineer (or the layout design tool) modifies the layouts received in operation 1110 to generate a plurality of modified layouts. For example, the layout engineer (or the layout design tool) alters the order of the components (C1-C4) and/or adjusts the length of the metal line 310 and/or the length of the metal line 320, thereby balancing the resistance (and/or the capacitance) of the signal line (SL) and the resistance (and/or the capacitance) of the complement signal line (SLB).

In operation 1130, the layout design tool simulates the modified layouts. In operation 1140, the layout design tool determines the offset voltages of the layouts simulated in operation 1130. In operation 1150, the layout engineer (or the layout design tool) selects one of the layouts simulated in operation 1130, e.g., the layout having an offset voltage nearest to 0V. In operation 1160, the device manufacturing tool fabricates the device 100 using the layout selected in operation 1150.

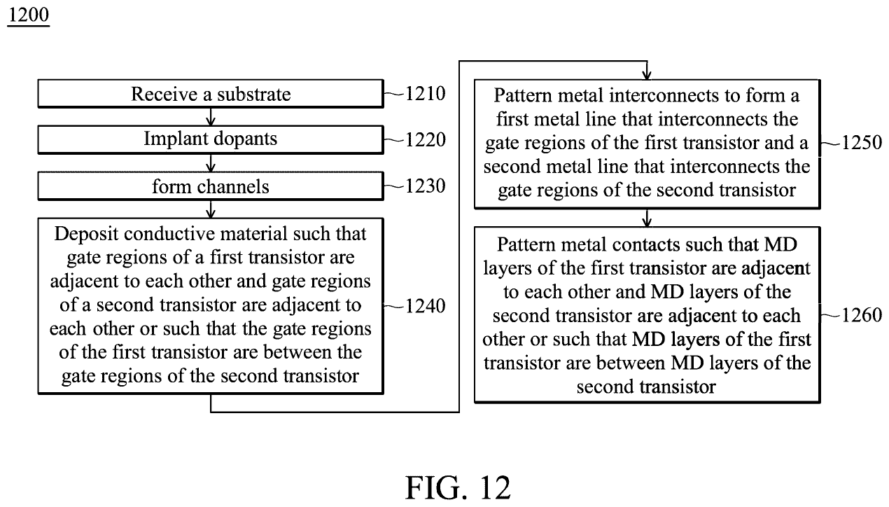

FIG. 12 is a flow chart illustrating an exemplary method 1200 of manufacturing the device 100 using the sense amplifier 200 layout 300-800 in accordance with various embodiments of the present disclosure. The example method 1200 will now be described with further reference to FIGS. 2-8 for ease of understanding. It is understood that the method 1200 is applicable to structures other than those of FIGS. 2-8. Further, it is understood that additional operations can be provided before, during, and after the method 1200, and some of the operations described below can be replaced or eliminated, in an alternative embodiment of the method 1200.

In operation 1210, the device manufacturing tool receives a substrate. Examples of materials for the substrate include silicon, germanium, III-V semiconductors, other suitable substrate materials, and alloys thereof. In operation 1220, the device manufacturing tool fabricates the source and drain regions (S1-S8, D1-D8) of the transistors (T2, T4) of the sense amplifier 200 over the substrate using the transistor (T2, T4) layout portions (T2′, T4′). In this exemplary embodiment, operation 1220 includes: implanting or diffusing dopants in predetermined regions of the substrate to form the source and drain regions (S1-S8, D1-D8) of the transistors (T2, T4). Examples of materials for the dopants include arsenic, phosphorous, boron, gallium, antimony, other suitable source/drain dopants, and alloys thereof.

In operation 1230, the device manufacturing tool lightly dopes the region between the source and drain regions (S1-S8, D1-D8), also known as the channel, to control conductivity of the channel. In an alternative embodiments, the device manufacturing tool leaves the channel undoped. In operation 1240, the device manufacturing tool fabricates the gate regions (G1-G8) of the transistors (T2, T4) of the sense amplifier 200 over the substrate using the transistor (T2, T4) layout portions (T2′, T4′). In this exemplary embodiment, operation 1240 includes: depositing a thin layer of insulating material, e.g., silicon dioxide, on the channel to form a gate oxide; depositing a conductive material on the gate oxide; and patterning the conductive material to form the gate regions (G1-G8). Examples of materials for the gate regions (G1-G8) include polysilicon, metal, other suitable gate region materials, and alloys thereof.

In operation 1250, the device manufacturing tool fabricates metal interconnects that includes the metal lines 310, 320 using the transistor (T2, T4) layout portions (T2′, T4′), respectively. In this exemplary embodiment, operation 1250 includes depositing conductive material over the substrate and patterning the conductive material to form the metal lines 310, 320. Examples of materials for the metal lines 310, 320 include aluminum, copper, other conductive materials, other suitable metal line 310, 320 materials, and alloys thereof. In operation 1260, the device manufacturing tool deposits metal contacts on the source and drain regions (S1-S8, D1-D8) and patterns the metal contacts to form the MD layers (MD1-M4) using the transistor (T2, T4) layout portions (T2′, T4′). Examples of materials for the MD layers (MD1-MD4) include aluminum, copper, other conductive materials, other suitable MD layers (MD1-MD4) materials, and alloys thereof.

In an embodiment, a device comprises a memory circuit and a sense amplifier. The memory circuit includes a complementary signal lines and a plurality of memory cells connected between the complementary signal lines. The sense amplifier amplifies a voltage difference between the complementary signal lines and includes first, second, third, and fourth components. The first component has a first gate region of a first transistor. The second component has a first gate region of a second transistor. The third component has a second gate region of the first transistor. The fourth component has a second gate region of the second transistor. Each of the first and second gate regions of the first and second transistors extends in a first direction. The first, second, third, and fourth components are arranged along a second direction transverse to the first direction.

In another embodiment, a device comprises a memory circuit and a sense amplifier. The memory circuit includes complementary signal lines and a plurality of memory cells connected between the complementary signal lines. The sense amplifier amplifies a voltage difference between the complementary signal lines and includes a plurality of first gate regions, a plurality of second gate regions, and first and second metal lines. The first gate regions each extend in a first direction. The first metal line extends in a second direction transverse to the first direction and interconnects the first gate regions. The second gate regions each extend in the first direction and overlaps the first metal line in a third direction transverse to the first and second directions. The second metal line extends in the second direction, interconnects the second gate regions, and overlaps the first gate regions in the third direction.

In another embodiment, a method comprises receiving a layout of a sense amplifier and fabricating a device using the layout. The layout 300 includes a plurality of components and first and second metal lines. A first component of the plurality of components includes an MD layer MD1 of a first transistor and source, drain, and gate regions of a second transistor. A second component of the plurality of components includes the MD layer of the first transistor of the first transistor and the source, drain, and gate regions of the second transistor. A third component of the plurality of components includes source, drain, and gate regions of the first transistor and an MD layer of the second transistor. A fourth component of the plurality of components includes the source, drain, and gate regions of the first transistor and the MD layer of the second transistor. The first metal line interconnects the gate regions of the first transistor. The second metal line interconnects the gate regions of the second transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device comprising:
a memory circuit including:
complementary signal lines; and
a plurality of memory cells connected between the complementary signal lines; and
a sense amplifier configured to amplify a voltage difference between the complementary signal lines and including:
a first component having a first gate region of a first transistor;
a second component having a first gate region of a second transistor;
a third component having a second gate region of the first transistor; and
a fourth component having a second gate region of the second transistor, wherein:
each of the first and second gate regions of the first and second transistors extends in a first direction; and
the first, second, third, and fourth components are arranged along a second direction transverse to the first direction.

2. The device of claim 1, wherein the second component is interposed between the first and third components.

3. The device of claim 2, wherein the third component is interposed between the second and fourth components.

4. The device of claim 1, wherein the first component is between the second and third components.

5. The device of claim 4, wherein the third component is interposed between the first and fourth components.

6. The device of claim 1, wherein the third component is between the first and second components.

7. The device of claim 6, wherein the second component is interposed between the third and fourth components.

8. The device of claim 1, wherein the second component is between the third and fourth components.

9. The device of claim 8, wherein the third component is interposed between the first and second components.

10. The device of claim 1, wherein the first and second transistors overlap each other in a third direction transverse to the first and second directions.

11. The device of claim 1, further comprising a sense amplifier node connected to a source/drain region of the first transistor and a source/drain region of the second transistor and including a plurality of first metal lines that each extend in the first direction and a second metal line that extends in the second direction and interconnecting the first metal lines.

12. The device of claim 11, further comprising a third transistor connected to the sense amplifier node and including a plurality of third gate regions and a third metal line interconnecting the third gate regions.

13. The device of claim 11, further comprising a supply voltage node overlapping the sense amplifier node in a third direction transverse to the first and second directions and includes one or more metal lines that each extend in the first direction.

14. A device comprising:
a memory circuit including:
complementary signal lines; and
a plurality of memory cells connected between the complementary signal lines; and
a sense amplifier configured to amplify a voltage difference between the complementary signal lines and including:
a plurality of first gate regions that each extend in a first direction;
a first metal line extending in a second direction transverse to the first direction and interconnecting the first gate regions;
a plurality of second gate regions that each extend in the first direction and overlapping the first metal line in a third direction transverse to the first and second directions; and
a second metal line extending in the second direction, interconnecting the second gate regions, and overlapping the first gate regions in the third direction.

15. The device of claim 14, wherein the second metal line has substantially the same length as the first metal line.

16. The device of claim 14, wherein the second metal line has a shorter or longer length than the first metal line.

17. A method comprising:
receiving a layout of a sense amplifier, wherein:
the layout includes a plurality of components and first and second metal lines;
a first component of the plurality of components includes an MD layer of a first transistor and source, drain, and gate regions of a second transistor;
a second component of the plurality of components includes the MD layer of the first transistor of the first transistor and the source, drain, and gate regions of the second transistor;
a third component of the plurality of components includes source, drain, and gate regions of the first transistor and an MD layer of the second transistor;
a fourth component of the plurality of components includes the source, drain, and gate regions of the first transistor and the MD layer of the second transistor;
the first metal line interconnects the gate regions of the first transistor; and
the second metal line interconnects the gate regions of the second transistor; and fabricating a device using the layout.

18. The method of claim 17, wherein the second component is between the first and third components and the third component is between the second and fourth components.

19. The method of claim 17, wherein the first and third components are adjacent to each other and are between the second and fourth components.

20. The method of claim 17, wherein the first and third components are adjacent to each other and the second and fourth components are adjacent to each other.
